(19) United States
(12) Patent Application Publication
(10) Pub. No.: US 2025/0085639 A1
(43) Pub. Date: Mar. 13, 2025

(54) METHODS AND SYSTEMS FOR ELECTRIC FIELD-ASSISTED LITHOGRAPHY

(71) Applicant: ASM IP Holding B.V., Almere (NL)

(72) Inventor: Fatemeh Davodi, Helsinki (FI)

(21) Appl. No.: 18/825,635

(22) Filed: Sep. 5, 2024

Related U.S. Application Data
(60) Provisional application No. 63/581,487, filed on Sep. 8, 2023.

(51) Int. Cl. G03F 7/00

(52) U.S. Cl. CPC G03F 7/70091; G03F 7/70033

(57) ABSTRACT

Lithographical systems and methods. Embodiments of methods disclosed herein comprise exposing a substrate to an electric field while exposing the substrate to electromagnetic radiation. Thus, dose reduction can be obtained.

### CROSS-REFERENCE TO RELATED APPLICATION(S)

This application claims the benefit of U.S. Provisional Application 63/581,487 filed on Sep. 8, 2023, the entire contents of which are incorporated herein by reference.

### FIELD OF INVENTION

The present disclosure is in the field of lithography, e.g. EUV lithography, for patterning of substrates such as semiconductor substrates.

### BACKGROUND OF THE DISCLOSURE

Extreme ultraviolet (EUV) lithography is an enabling technique for advanced semiconductor processing. It remains costly though, featuring a high cost per photon. Thus, dose reduction is desired, with “dose” referring to the amount of photons needed for full exposure of a resist.

### SUMMARY OF THE DISCLOSURE

Described herein are systems for lithographically patterning semiconductor substrates comprising a electromagnetic (EM) radiation source, an optical assembly, and an exposure chamber comprising a substrate support and an electrode assembly; the EM radiation source being configured for generating electromagnetic radiation; the optical assembly being constructed and arranged for directing the EM radiation towards the substrate support; the substrate support being constructed and arranged for supporting a semiconductor substrate; the electrode assembly being constructed and arranged for applying an electric field to an EM-sensitive layer comprised in the semiconductor substrate.

In some embodiments, the electrode assembly is constructed and arranged for laterally applying the electric field to the EM-sensitive layer.

In some embodiments, the electrode assembly comprises two electrodes that are positioned adjacent to the substrate support.

In some embodiments, the electrode assembly comprises two electrodes, each comprising a plurality of fingers that, together, form an interdigitated pattern.

In some embodiments, ones from the plurality of fingers are mutually parallel.

In some embodiments, the electrode assembly is constructed and arranged for transversally applying the electric field to the EM-sensitive layer.

In some embodiments, the electrode assembly comprises a first electrode and a second electrode, wherein the first electrode is electrically connected to the substrate support, and wherein the second electrode is positioned substantially parallel with the substrate, between the substrate and the EM radiation source.

In some embodiments, the electrode assembly comprises a first electrode and a second electrode, wherein the first electrode is electrically connected to the substrate, and wherein the second electrode is positioned substantially parallel with the substrate, between the substrate and the EM radiation source.

In some embodiments, the EM radiation source comprises an extreme ultraviolet (EUV) source.

Further described herein is a method that comprises providing a system comprising an electromagnetic (EM) radiation source, a optical assembly, and an exposure chamber comprising a substrate support and an electrode assembly; positioning a substrate on the substrate support, the substrate comprising an EM-sensitive layer; exposing the substrate to EM radiation; and, while exposing the substrate to EM radiation, applying an electric field to the EM-sensitive layer by means of an electrode pair comprising a first electrode and a second electrode.

In some embodiments, the EM radiation comprises extreme ultraviolet (EUV) radiation.

In some embodiments, the electric field enhances secondary electron generation while exposing the substrate to EM radiation.

In some embodiments, the electric field comprises a DC field.

In some embodiments, the electric field comprises an AC field.

In some embodiments, the electric field is applied substantially parallel to the EM-sensitive layer.

In some embodiments, the electric field is applied substantially perpendicular to the EM-sensitive layer.

In some embodiments, the electric field comprises a component which is oblique with respect to the EM-sensitive layer.

In some embodiments, the EM-sensitive layer comprises an EUV resist and at least one of an underlayer, a glue layer, and an electron reflector layer.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates an embodiment of a system 100 for forming a pattern on a substrate.

FIGS. 2-6 illustrate embodiments of electrode assemblies 200-600 as described herein.

FIGS. 7-9 illustrate embodiments of structures as described herein.

FIG. 10 illustrates an embodiment of a method as described herein.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

Described herein are systems for lithographically patterning semiconductor substrates. The systems can comprise a electromagnetic (EM) radiation source, an optical assembly, and an exposure chamber. The exposure chamber can comprise a substrate support and an electrode assembly. The EM radiation source can be configured for generating electromagnetic radiation. The optical assembly can be constructed and arranged for directing the EM radiation towards the substrate support. The substrate support can be constructed and arranged for supporting a semiconductor substrate. The electrode assembly can be constructed and arranged for applying an electric field to an EM-sensitive layer comprised in the semiconductor substrate. In some embodiments, the EM radiation source comprises an extreme ultraviolet (EUV) source.

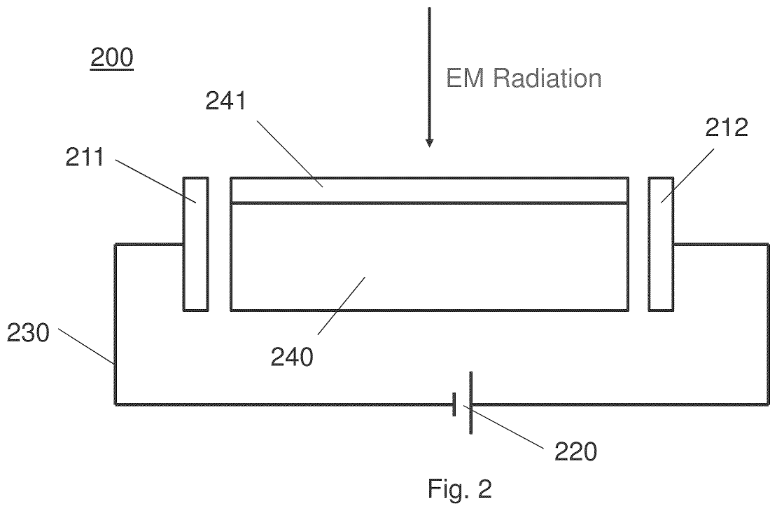

In some embodiments, the electrode assembly is constructed and arranged for laterally applying the electric field to the EM-sensitive layer. Examples of such embodiments are illustrated by means of FIGS. 2, 5, and 6.

In some embodiments, the electrode assembly comprises two electrodes that are positioned adjacent to the substrate support. An example of such an embodiment is illustrated by means of FIG. 2.

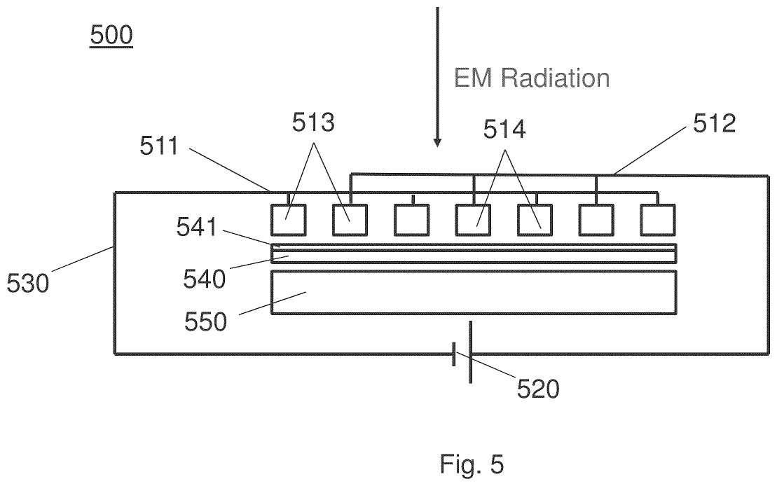

In some embodiments, the electrode assembly comprises two electrodes, each comprising a plurality of fingers that, together, form an interdigitated pattern. An example of such an embodiment is illustrated by means of FIGS. 5 and 6.

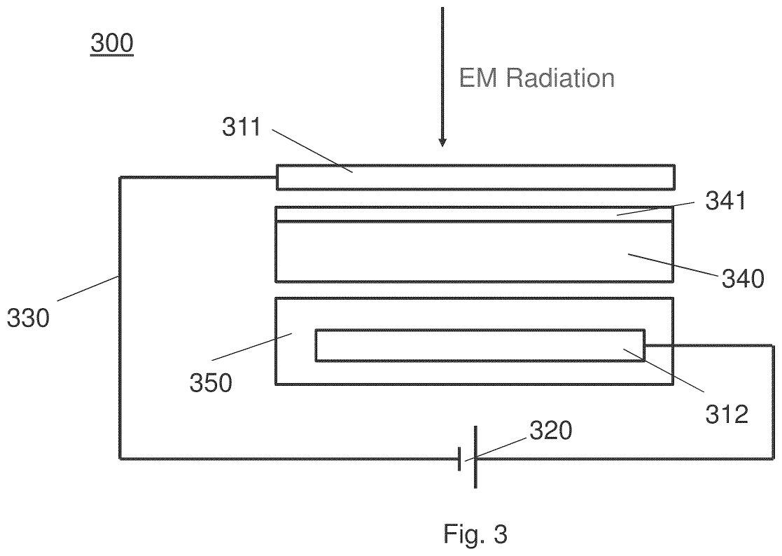

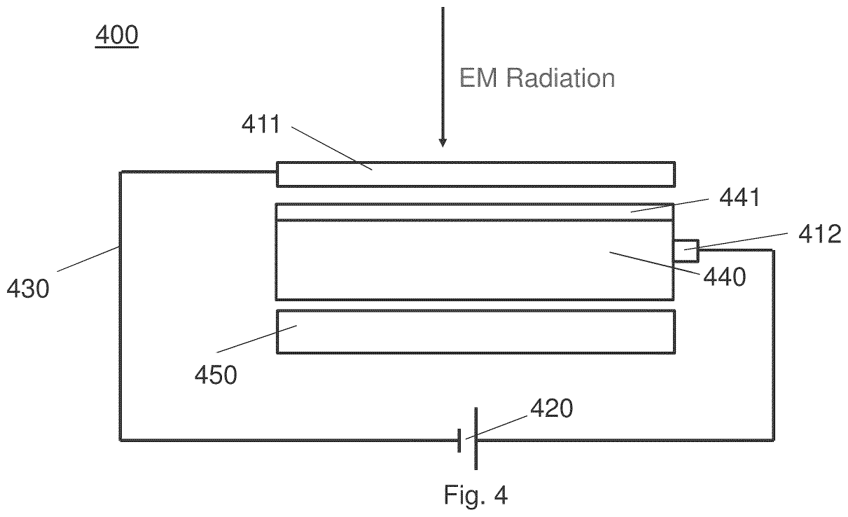

In some embodiments, the electrode assembly is constructed and arranged for transversally applying the electric field to the EM-sensitive layer. Examples of such embodiments are illustrated by means of FIGS. 3 and 4.

In some embodiments, the electrode assembly comprises a first electrode and a second electrode. The first electrode can be electrically connected to the substrate support. The second electrode can be positioned substantially parallel with the substrate, between the substrate and the EM radiation source. An example of such an embodiment is illustrated by means of FIG. 3.

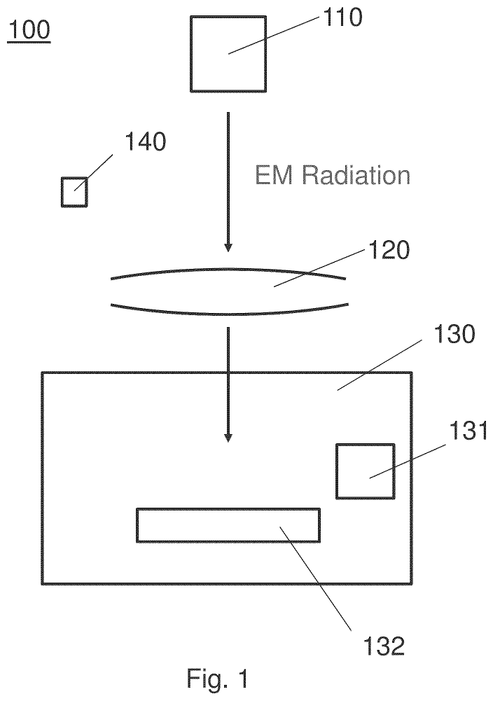

With reference to FIG. 1, described herein is a particular embodiment of a system 100 for forming a pattern on a substrate. The system 100 comprises an electromagnetic (EM) radiation source 110. The EM radiation source 110 can be constructed and arranged to produce one or more of visible light, ultraviolet (UV) radiation, and extreme ultraviolet (EUV) radiation. The EM radiation can pass through an optical assembly 120 to arrive in an exposure chamber 130. The optical assembly 120 can comprise one or more lenses. Additionally or alternatively, the optical assembly 120 can comprise one or more mirrors, for example Bragg reflectors. The exposure chamber can comprise a substrate support 131 and an electrode assembly 132. The substrate support 131 can be constructed and arranged to support a substrate such as a semiconductor wafer during exposure to EM radiation. The substrate comprises an EM-sensitive layer, such as a resist, such as one or more of a UV resist, an EUV resist, a chemically amplified resist, and a metalorganic resist. The exposure chamber 130 further comprises an electrode assembly 132. The electrode assembly can be constructed and arranged for applying an electric field over the EM-sensitive layer. Thus, the EM radiation dose, e.g. the EUV dose, required to develop the EM-sensitive layer after exposure can be advantageously reduced.

FIG. 2 shows an embodiment of an electrode assembly 200 as described herein. The embodiment of FIG. 2 comprises two electrodes 211,212 which can be positioned adjacent to, i.e. sideways of, a substrate 240 that can be supported by a substrate support (not shown). Thus, an electric field can be applied laterally, i.e. in the plane of, a patternable layer 241 comprised in the substrate 240. The electrodes 211,212 can be connected to a voltage source 220 by means of conductive wires 230. FIG. 2 shows an electrode assembly 200 with a DC voltage source 220. Additionally or alternatively, the electrode assembly 200 can comprise an AC voltage source.

FIG. 3 shows another embodiment of an electrode assembly 300 as described herein. The embodiment of FIG. 3 comprises two electrodes 311,312. A first electrode 311 is positioned parallel to a substrate 340 that comprises an EM radiation-patternable layer 341, at the side of the substrate comprising the EM radiation-sensitive layer 341. The first electrode 311 can be transparent, partially transparent, or substantially transparent, to EUV radiation. For example, the first electrode can have a thickness which is sufficiently thin to allow a substantial portion of EUV radiation to pass through. For example, the first electrode can have a thickness of at least 1.0 nm to at most 10 μm, or of at least 1.0 nm to at most 10 nm, or of at least 10 nm to at most 100 nm, or of at least 100 nm to at least 1 μm, or of at least 1 μm to at most 10 μm. For example, the first electrode can allow 10 to 99%, or 20 to 99%, or 50 to 99%, or 70 to 99%, or more than 99%, or substantially all incident EUV radiation to pass through. Note that while all materials absorb EUV radiation at least to some extent,

A second electrode is comprised in a substrate support 350 which supports the substrate 340 at the far side of the substrate 340. The first electrode 311 and the second electrode 312 can be parallel, or can be substantially parallel. Thus, an electric field can be applied transversally to the patternable layer 341, i.e. perpendicular to the plane of the patternable layer 341. The electrodes 311,312 can be connected to a voltage source 320 by means of conductive wires 330. FIG. 3 shows an electrode assembly 300 with a DC voltage source 320. Additionally or alternatively, the electrode assembly 300 can comprise an AC voltage source.

FIG. 4 shows another embodiment of an electrode assembly 400 as described herein. The embodiment of FIG. 4 comprises two electrodes 411,412. A first electrode 411 is positioned parallel, or substantially parallel, to a substrate 440 that comprises an EM radiation-patternable layer 441, at the side of the substrate comprising the EM radiation-sensitive layer 441. The first electrode can be transparent to EM radiation. A second electrode 412 electrically contacts the substrate 440. It shall be understood that at least in this embodiment, the substrate comprises an electrical conductor such as a metal or a doped or undoped semiconductor. The first electrode 411 and the substrate 440 can be parallel, or can be substantially parallel. Thus, an electric field can be applied transversally to the patternable layer 441, i.e. perpendicular to the plane of the patternable layer 441. The electrodes 411,412 can be connected to a voltage source 440 by means of conductive wires 430. FIG. 4 shows an electrode assembly 400 with a DC voltage source 420. Additionally or alternatively, the electrode assembly 400 can comprise an AC voltage source.

FIG. 5 shows another embodiment of an electrode assembly 500 as described herein. The embodiment of FIG. 5 comprises two interdigitated electrodes 511,512. A first electrode 511 and a second electrode 512 each comprise a plurality of alternating conductive wires 513, 514 or sheets or the like which are particularly positioned parallel, or substantially parallel, to one another and to the substrate. Wires 513 from the first electrode 511 are alternated with wires 514 from the second electrode 512 to form an interdigitated pattern. The first and second electrodes 511,512 are positioned at the side of the substrate comprising the EM radiation-sensitive layer 541. The first electrode can be transparent to EM radiation. Thus, an electric field can be applied substantially parallel to, i.e. substantially in the plane of, the patternable layer 541. The electrodes 511,512 can be connected to a voltage source 540 by means of conductive wires 530. FIG. 5 shows an electrode assembly 500 with a DC voltage source 520. Additionally or alternatively, the electrode assembly 500 can comprise an AC voltage source.

An embodiment of electrodes 611,612 which can be employed in the electrode assembly 500 of FIG. 5, are shown in FIG. 6. The first 611 and second 612 electrodes comprise a plurality of first electrode fingers 613 and second electrode fingers 614, respectively. The first electrode fingers 613 and second electrode fingers 614 are arranged in an interlacing, or interdigitated, pattern.

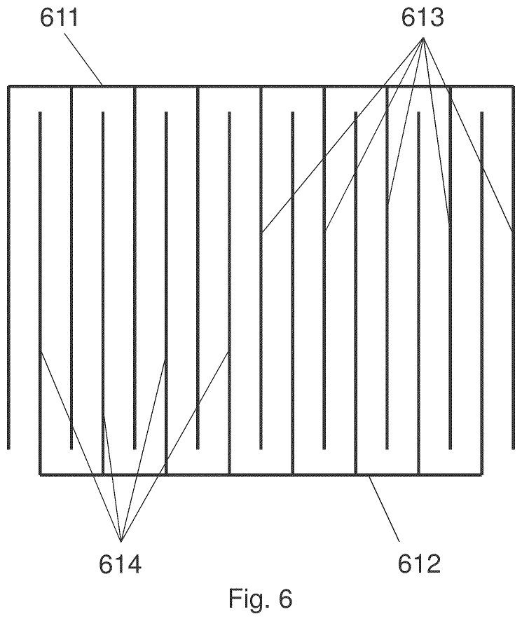

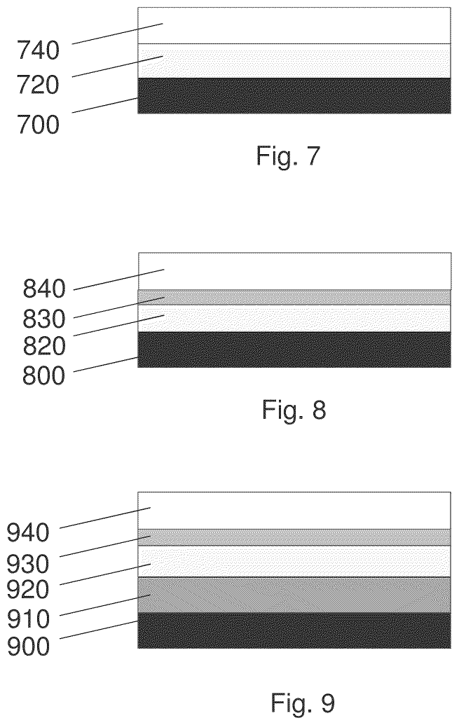

In some embodiments, the EM-sensitive layer comprises a layer, i.e. EUV resist, which is sensitive to EUV radiation. Exemplary structures comprising an EUV resist are shown in FIGS. 7 to 9.

FIG. 7 shows a structure that comprises a substrate 700, an underlayer 720 overlying the substrate 700, and a resist 740 overlying the underlayer 720. Suitable underlayers are described in any one of US patent application publication nos. US20230071197A1, US20230091094A1, and US20230077088A1, which are incorporated herein by reference in their entirety.

FIG. 8 shows a structure that comprises a substrate 800, an underlayer 820 overlying the substrate 800, a glue layer 830 overlying the underlayer 820, and a resist 840 overlying the glue layer 830. Advantageously, the glue layer 830 can provide adhesion between the underlayer 820 and the resist 840. Exemplary glue layers and methods of their manufacture are described in U.S. Pat. No. 11,735,422 which is incorporated herein by reference in its entirety.

FIG. 9 shows a structure that comprises a substrate 900, an electron reflecting layer 910 overlying the substrate, an underlayer 920 overlying the electron reflecting layer 910, a glue layer 930 overlying the underlayer 920, and a resist 940 overlying the glue layer 930. Advantageously, the electron reflection layer 910 can reflect electrons generated in the underlayer 920, which can lead to additional dose reduction. Suitable electron reflection layers 910 and methods of their manufacture are described in U.S. provisional application No. 63/484,346 which is incorporated herein by reference in its entirety.

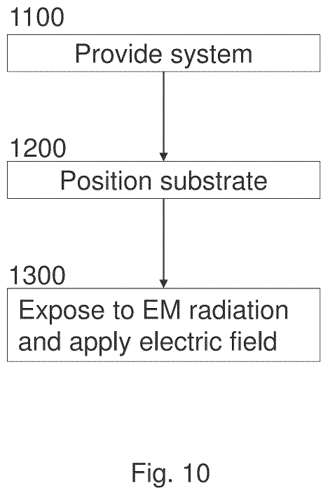

Further described herein, and with reference to FIG. 10, is an embodiment of a lithography method. The method can comprise a step 1100 of providing a system comprising an electromagnetic (EM) radiation source, an optical assembly, and an exposure chamber. The exposure chamber can in turn comprise a substrate support and an electrode assembly. The method can further comprise a step 1200 of positioning a substrate on the substrate support. The substrate can comprise an EM-sensitive layer. The method can further comprise a step 1300 of exposing the substrate to EM radiation such as UV radiation or EUV radiation. While exposing the substrate to EM radiation, the method can comprise applying an electric field to the EM-sensitive layer by means of an electrode pair comprising a first electrode and a second electrode. For example, the electric field can have a magnitude of at least 0.1 kV/cm to at most 100 kV/cm, e.g. of at least 0.1 kV/cm to at most 1.0 kV/cm, or of at least 1.0 kV/cm to at most 10 kV/cm or of at least 10 kV/cm to at most 100 kV/cm.

Advantageously, the electric field can enhance secondary electron generation while exposing the substrate to EM radiation. Suitable electric field can comprise constant or quasi-constant fields, i.e. DC fields. Suitable electric fields can comprise time-varying fields, i.e. AC fields. For example, the AC field can have a frequency of at least 1 Hz to at most 1 MHz, such as 10 Hz, 100 Hz, 1 kHz, 10 kHz, or 100 kHz.

In some embodiments, the electric field can be applied substantially parallel to the EM-sensitive layer. For example, the configuration of at least one of FIGS. 2 and 5 can be used for this purpose.

In some embodiments, the electric field is applied substantially perpendicular to the EM-sensitive layer. For example, the configuration of at least one of FIGS. 3 and 4 can be used for this purpose.

In some embodiments, the electric field comprises a component which is oblique with respect to the EM-sensitive layer.

In some embodiments, the EM-sensitive layer comprises an EUV resist and at least one of an underlayer, a glue layer, and an electron reflector layer. Embodiments of such EM-sensitive layers are illustrated by means of FIGS. 7, 8, and 9. Indeed, EUV dose reduction can rely on producing more secondary electron yield inside the photo resist. By applying an external field to the stacked layer we can simply improve the generation and more importantly escape of the secondary electron generated inside the stacked layer and guide them to the photo resist. Without wishing the invention to be bound by any particular theory or mode of operation, it is believed that EUV dose reduction can be achieved by subjecting a substrate simultaneously to EUV radiation and to an electric field by one or more of the following mechanisms: avalanche multiplication of secondary electrons, Pockel's effect i.e. an electric field-induced change of refractive index for EUV radiation, and the Kerr effect i.e. an electric field-induced EUV polarization/propagation direction change.

For example, without the present disclosure being bound by any particular theory or mode of operation, the Pockels effect is characterized by a change in the refractive index of the material in the presence of an external electric field. The amount of change in the refractive index depends on the magnitude and direction of the applied electric field, as well as the properties of the material. The change in refractive index can be described by the Pockels equation, which relates the refractive index change to the electric field strength and the so-called Pockels coefficient of the material: Δn=rE, where Δn is the change in refractive index, r is the Pockels coefficient, and E is the electric field strength. The Pockels coefficient is a material-specific constant that depends on the crystal structure and symmetry of the material. The Pockels effect can be used to control the polarization and propagation direction of electromagnetic waves, including EUV radiation, by placing the material with the appropriate Pockels coefficient in the path of the wave and applying an external electric field.

For example, without the present disclosure being bound by any particular theory or mode of operation, the Kerr effect is characterized by a change in refractive index in the presence of an external electric field. The amount of change in the refractive index depends on the magnitude and direction of the applied electric field, as well as the properties of the vacuum, such as its density and temperature. The change in refractive index can be described by the Kerr equation, which relates the refractive index change to the electric field strength and the so-called Kerr constant of the vacuum: Δn=n\hat{ }3*(2π/λ)\hat{ }2*K*E\hat{ }2, where Δn is the change in refractive index, n is the refractive index of the vacuum, λ is the wavelength of the radiation, K is the Kerr constant of the vacuum, and E is the electric field strength. The Kerr effect is relatively weak compared to other effects, such as the Pockels effect, and is usually only observable at very high electric field strengths. However, it can still play a role in certain applications. Indeed, the refractive index of a material affects EUV radiation in several ways. The refractive index is a measure of how much the speed of light is reduced when it propagates through a material, compared to when it propagates through a vacuum. This reduction in speed results from the interaction between the electromagnetic wave and the charged particles in the material, which causes the wave to slow down and change direction. The refractive index of a material determines how much the path of an EUV wave is bent as it passes through the material, which is determined by Snell's law of refraction. When an EUV wave passes from one material into another with a different refractive index, its direction of propagation changes, which is called refraction. The amount of refraction depends on the difference in refractive index between the two materials, as well as the angle of incidence of the wave. For EUV radiation, which has a very short wavelength, the refractive index can vary significantly with wavelength and material properties.

1. A system for lithographically patterning semiconductor substrates comprising:
an electromagnetic (EM) radiation source;
an optical assembly; and
an exposure chamber comprising a substrate support and an electrode assembly,
the EM radiation source being configured for generating electromagnetic radiation,
the optical assembly being constructed and arranged for directing the EM radiation towards the substrate support,
the substrate support being constructed and arranged for supporting a semiconductor substrate, and
the electrode assembly being constructed and arranged for applying an electric field to an EM-sensitive layer comprised in the semiconductor substrate.

2. The system according to claim 1, wherein the electrode assembly is constructed and arranged for laterally applying the electric field to the EM-sensitive layer.

3. The system according to claim 2, wherein the electrode assembly comprises two electrodes that are positioned adjacent to the substrate support.

4. The system according to claim 2, wherein the electrode assembly comprises two electrodes, each comprising a plurality of fingers that, together, form an interdigitated pattern.

5. The system according to claim 4, wherein ones from the plurality of fingers are mutually parallel.

6. The system according to claim 1, wherein the electrode assembly is constructed and arranged for transversally applying the electric field to the EM-sensitive layer.

7. The system according to claim 6, wherein the electrode assembly comprises a first electrode and a second electrode, wherein the first electrode is electrically connected to the substrate support, and wherein the second electrode is positioned substantially parallel with the semiconductor substrate, between the semiconductor substrate and the EM radiation source.

8. The system according to claim 6, wherein the electrode assembly comprises a first electrode and a second electrode, wherein the first electrode is electrically connected to the semiconductor substrate, and wherein the second electrode is positioned substantially parallel with the semiconductor substrate, between the semiconductor substrate and the EM radiation source.

9. The system according to claim 1, wherein the EM radiation source comprises an extreme ultraviolet (EUV) source.

10. A method comprising:
providing a system comprising an electromagnetic (EM) radiation source, an optical assembly, and an exposure chamber comprising a substrate support and an electrode assembly;
positioning a substrate on the substrate support, the substrate comprising an EM-sensitive layer;
exposing the substrate to EM radiation; and
while exposing the substrate to EM radiation, applying an electric field to the EM-sensitive layer by an electrode pair comprising a first electrode and a second electrode.

11. The method according to claim 10, wherein the EM radiation comprises extreme ultraviolet (EUV) radiation.

12. The method according to claim 10, wherein the electric field enhances secondary electron generation while exposing the substrate to EM radiation.

13. The method according to claim 10, wherein the electric field comprises a DC field.

14. The method according to claim 10, wherein the electric field comprises an AC field.

15. The method according to claim 10, wherein the electric field is applied substantially parallel to the EM-sensitive layer.

16. The method according to claim 10, wherein the electric field is applied substantially perpendicular to the EM-sensitive layer.

17. The method according to claim 10, wherein the electric field comprises a component which is oblique with respect to the EM-sensitive layer.

18. The method according to claim 10, wherein the EM-sensitive layer comprises an EUV resist and at least one of an underlayer, a glue layer, and an electron reflector layer.
